(19) United States
(12) Patent Application Publication
(10) Pub. No.: US 2011/0108412 A1
(43) Pub. Date: May 12, 2011

(54) Method to Improve Corrosion Performance of Exchange Coupled Granular Perpendicular Media

(75) Inventors: Lei Zhu, Singapore (SG); Feng Li, Singapore (SG); Su Yang, Singapore (SG); Jing Gui, Fremont, CA (US)

(73) Assignee: Seagate Technology LLC, Scotts Valley, CA (US)

(21) Appl. No.: 12/942,730

(22) Filed: Nov. 9, 2010

Related U.S. Application Data
(62) Division of application No. 12/178,431, filed on Jul. 23, 2008.

(51) Int. Cl. C23C 14/34; C23C 14/06

(52) U.S. Cl. 204/192.1

(57) ABSTRACT

The invention relates to a granular perpendicular magnetic recording medium comprising a top magnetic layer on a granular layer wherein the magnetic layer comprises a continuous Co alloy film that results in the recording medium having less than 10% CoOx on the surface of the protective overcoat when the recording medium is exposed to 80% relative humidity at 80° C. for 4 days.

### RELATED PATENT DOCUMENTS

This application is a division of U.S. patent application Ser. No. 12/178,431 filed on Jul. 23, 2008, which is incorporated herein by reference in its entirety.

### BACKGROUND

Perpendicular recording media are being developed for higher density recording as compared to longitudinal media. The thin-film perpendicular magnetic recording medium comprises a substrate and a magnetic layer having perpendicular magnetic anisotropy, wherein the magnetic layer comprises an easy axis oriented substantially in a direction perpendicular to the plane of the magnetic layer. Typically, the thin-film perpendicular magnetic recording medium comprises a rigid NiP-plated Al alloy substrate, or alternatively a glass or glass-ceramic substrate, and successively sputtered layers. The sputtered layers can include one or more underlayers, one or more magnetic layers, and a protective overcoat. The protective overcoat is typically a carbon overcoat which protects the magnetic layer from corrosion and oxidation and also reduces frictional forces between the disc and a read/write head. In addition, a thin layer of lubricant may be applied to the surface of the protective overcoat to enhance the tribological performance of the head-disc interface by reducing friction and wear of the protective overcoat.

Granular perpendicular recording media is being developed for its capability of further extending the areal recording density as compared to conventional perpendicular recording media which is limited by the existence of strong exchange coupling between magnetic grains. In contrast to conventional perpendicular media wherein the magnetic layer is typically sputtered in the presence of inert gas, most commonly argon (Ar), deposition of a granular perpendicular magnetic layer utilizes a reactive sputtering technique wherein oxygen (O₂) is introduced, for example, in a gas mixture of Ar and O₂. Not wishing to be bound by theory, it is believed that the introduction of O₂ provides a source of oxygen that migrates into the grain boundaries forming oxides within the grain boundaries, and thereby providing a granular perpendicular structure having a reduced exchange coupling between grains.

Perpendicular recording media are more susceptible to corrosion because of their complex layered structure. Particularly in the case of exchange coupled granular designs, the complete coverage of the granular media layer by the top magnetic layer(s) having continuous Co alloy films is essential to ensure media reliability against environmental attack. However, increasing the thickness of the top magnetic layer to achieve complete coverage sacrifices the magnetic properties of the media.

### SUMMARY

The invention relates to a granular perpendicular magnetic recording medium comprising a top magnetic layer on a granular layer wherein the magnetic layer comprises a continuous Co alloy film that results in the recording medium having less than 10% CoOx on the surface of the protective overcoat when the recording medium is exposed to 80% relative humidity at 80° C. for 4 days.

Preferred embodiments of the invention are shown and described, by way of illustration of the best mode contemplated for carrying out the invention, in the following detailed description. As will be realized, this invention is capable of other and different embodiments, and its details are capable of modifications in various obvious respects, all without departing from the invention. Accordingly, the drawings and description are to be regarded as illustrative in nature and not as restrictive.

### BRIEF DESCRIPTION OF THE DRAWINGS

The present invention will be better understood by reference to the Detailed Description when taken together with the attached drawings, wherein:

FIG. 1 schematically shows a magnetic disk recording medium comparing longitudinal and perpendicular magnetic recording.

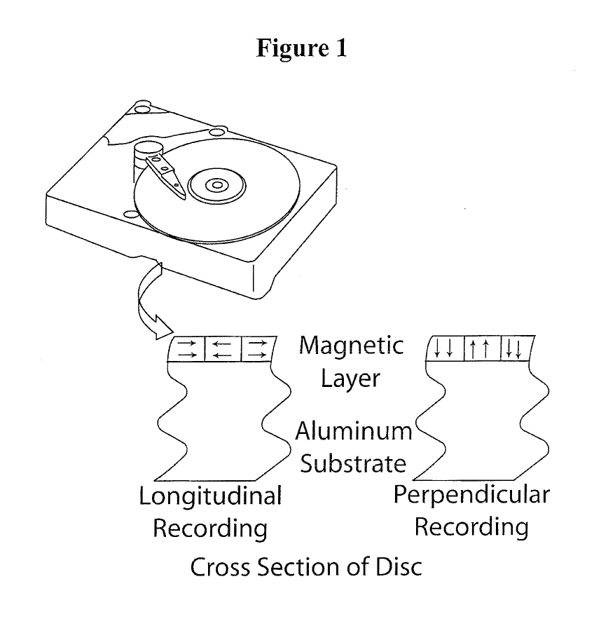

FIG. 2 shows a prior art granular perpendicular magnetic recording medium.

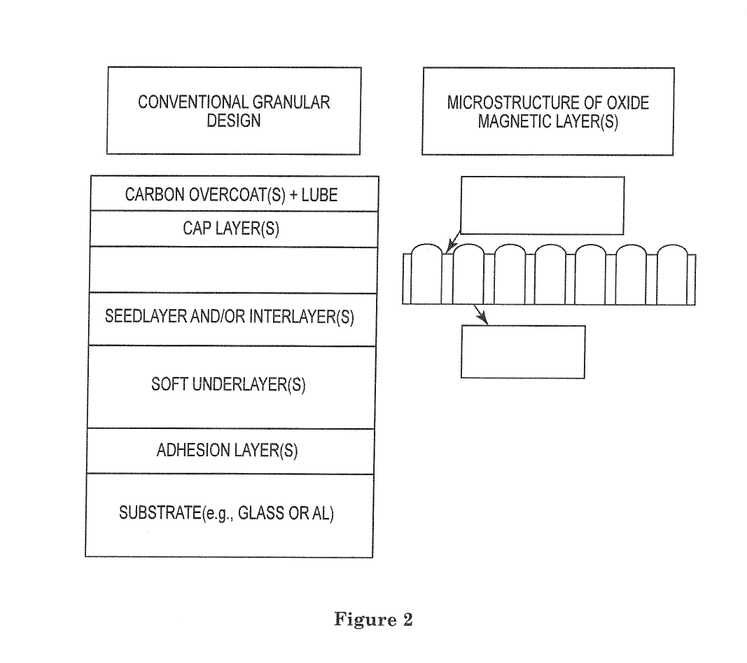

FIG. 3 illustrates corrosion performance as a function of the thickness of the top magnetic layer.

FIG. 4 shows a main effects plot of corrosion performance versus sputter power and sputter gas pressure for a fixed top magnetic layer film thickness.

### DETAILED DESCRIPTION

This invention relates to a method of improving the corrosion performance of granular perpendicular recording media by depositing the top magnetic layer of the media using high mobility conditions. Such conditions include high sputter power to enhance kinetic energy of ad-atoms and low sputter gas pressure to reduce the chance of kinetic energy loss by collisions. As used herein, “high sputter power” is defined as a sputter power that is at least 80% greater than the nominal setting for the particular system, and “low sputter gas pressure” is defined as a sputter gas pressure that is at least 20% less than the nominal setting for the particular system. For example, for the 250B and 200L magnetron systems, high sputter power is greater than about 0.8 kW and low sputter pressure is less than about 5 mTorr. These conditions lead to better coverage of the granular film underneath and result in improved corrosion performance.

One embodiment of the invention is a granular perpendicular magnetic recording medium comprising a top magnetic layer on a granular layer wherein the magnetic layer comprises a continuous Co alloy film that results in the recording medium having less than 10% CoOx on the surface of the protective overcoat when the recording medium is exposed to 80% relative humidity at 80° C. for 4 days or equivalent. According to one embodiment, a thickness of the continuous Co alloy film is from about 50 to about 80 A. For example, the thickness may be about 65 Å.

According to another embodiment, A method of improving the corrosion performance of granular perpendicular recording media comprises depositing a top magnetic layer onto a granular layer using high sputter power and/or low sputter gas pressure. For example, the sputter power may be greater than about 0.8 kW and the sputter gas pressure may be less than about 5 mTorr.

Another embodiment of the invention is a method of manufacturing a granular perpendicular magnetic recording medium comprising obtaining a substrate, depositing a granular layer, and depositing a top magnetic layer onto the granular layer, wherein the magnetic recording layer is deposited using high sputter power and/or low sputter gas pressure.

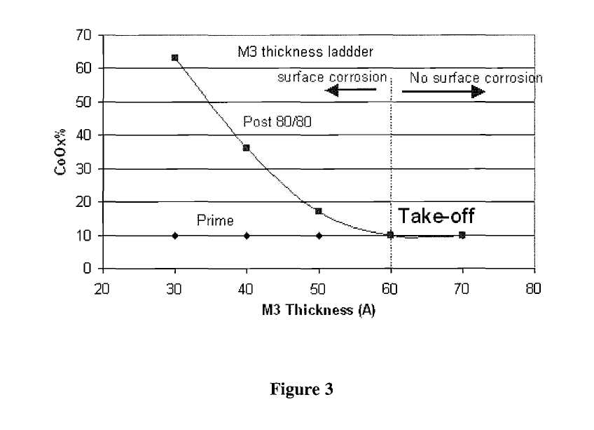

The method used for measuring corrosion performance is by ESCA (electron spectroscopy for chemical analysis). ESCA has its detection limit at 10% on CoOx. Any media whose CoOx detected by ESCA is less than 10% is referred as qualified (pass) and to the contrary, those whose CoOx detected by ESCA is more than 10% are referred as non-qualified (fail). Thus the ESCA standard measurement provides a direct gauge to assess the corrosion performance of the magnetic media. FIG. 3 shows a CoOx take-off chart shown illustrating the corrosion performance as a function of the thickness of the top magnetic layer (M3, as discussed in this disclosure).

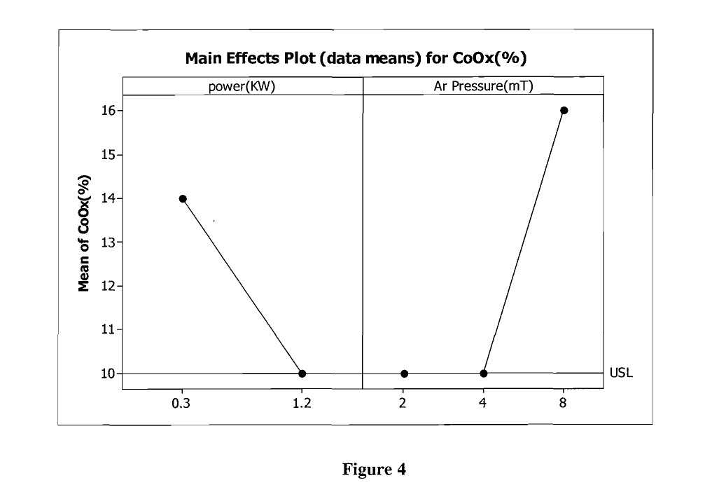

By way of illustration, FIG. 4 shows a main effects plot of corrosion performance versus sputter power and sputter gas pressure for a fixed top magnetic layer film thickness. It demonstrates that the amount of CoOx (cobalt oxide) on the disk surface after a four-day exposure to 80% relative humidity at 80° C. depends on sputter power and sputter gas pressure. Therefore, high mobility conditions, such as high sputter power or lower sputter gas pressure, result in un-detectable CoOx on the surface and, therefore, better corrosion performance.

An embodiment of the media comprises, from the bottom to the top:

(1) Substrate: polished glass, glass ceramics, or Al/NiP.
(2) Adhesion layers to ensure strong attachment of the functional layers to the substrates. One can have more than one layer for better adhesion or skip this layer if adhesion is fine. The examples include Ti alloys.
(3) Soft underlayers (SUL) include various design types, including a single SUL, antiferromagnetic coupled (AFC) structure, laminated SUL, SUL with pinned layer (also called anti-ferromagnetic exchange biased layer), and so on. The examples of SUL materials include FeₓCo_{y}B_{z} based, and CoₓZr_{y}Nb_{z}/CoₓZr_{y}Ta_{z} based series.
(4) Seed layer(s) and interlayer(s) are the template for Co (002) growth. Examples are RuX series of materials.
(5) Oxide containing magnetic layers (M1) can be sputtered with conventional granular media targets reactively (with Oₓ) and/or non-reactively. Multiple layers can be employed to achieve desired film property and performance. Examples of targets are Co_{100-x-y}Ptₓ(MO)_{y} and/or Co_{100-x-y-z}Ptₓ(X)_{y}(MO)_{z} series (X is the 3^{id} additives such as CR, and M is metal elements such as Si, Ti and Nb). Besides oxides in M1, the list can be easily extended such that the magnetic grains in M1 can be isolated from each other with dielectric materials at grain boundary, such as nitrides (MₓN_{y}), carbon (C) and carbides (MₓC_{y}). The examples of sputter targets are Co_{100-x-y}Ptₓ(MN)_{y}, Co_{100-x-y}Ptₓ(MC)_{y} and/or Co_{100-x-y}Ptₓ(X)_{y}(MN)_{z}, Co_{100-x-y}Ptₓ(X)_{y}(MC)_{z} series.
(6) Non-oxide containing magnetic layers (M2): The sputter targets can be used including conventional longitudinal media alloys and/or alloy perpendicular media. Desired performance will be achieved without reactive sputtering. Single layer or multiple layers can be sputtered on the top of oxide containing magnetic layers. The non-oxide magnetic layer(s) will grow epitaxially from oxide granular layer underneath. The orientation could eventually change if these layers are too thick. The examples of these are Co_{100-x-y-z-α}CrₓPt_{y}B_{z}X_{α}Y_{β}.
(7) Cap layer, which is optional for this design. In one variation, with dense grains and grain boundary without oxygen may not be necessary. Conventional carbon and lubrication can be adapted for the embodiment of the claimed media to achieve adequate mechanical performance.

The above layered structure of an embodiment is an exemplary structure. In other embodiments, the layered structure could be different with either less or more layers than those stated above.

Instead of the optional NiP coating on the substrate, the layer on the substrate could be any Ni-containing layer such as a NiNb layer, a Cr/NiNb layer, or any other Ni-containing layer. Optionally, there could be an adhesion layer between the substrate and the Ni-containing layer. The surface of the Ni-containing layer could be optionally oxidized.

The substrates used can be Al alloy, glass, or glass-ceramic. The magnetically soft underlayers according to present invention are amorphous or nanocrystalline and can be FeCoB, FeCoC, FeCoTaZr, FeTaC, FeSi, CoZrNb, CoZrTa, etc. The seed layers and interlayer can be Cu, Ag, Au, Pt, Pd, Ru-alloy, etc. The CoPt-based magnetic recording layer can be CoPt, CoPtCr, CoPtCrTa, CoPtCrB, CoPtCrNb, CoPtTi, CoPtCrTi, CoPtCrSi, CoPtCrAl, CoPtCrZr, CoPtCrHf, CoPtCrW, CoPtCrC, CoPtCrMo, CoPtCrRu, etc., deposited under argon gas (e.g., M2), or under a gas mixture of argon and oxygen or nitrogen (e.g., M1). Dielectric materials such as oxides, carbides or nitrides can be incorporated into the target materials also.

Embodiments of this invention include the use of any of the various magnetic alloys containing Pt and Co, and other combinations of B, Cr, Co, Pt, Ni, Al, Si, Zr, Hf, W, C, Mo, Ru, Ta, Nb, O and N, in the magnetic recording layer.

In a preferred embodiment the total thickness of SUL could be 100 to 5000 Å, and more preferably 600 to 2000 Å. There could be a more than one soft under layer. The laminations of the SUL can have identical thickness or different thickness. The spacer layers between the laminations of SUL could be Ta, C, etc. with thickness between 1 and 50 Å. The thickness of the seed layer, tₛ, could be in the range of 1 A<tₛ<50 Å. The thickness of an intermediate layer could be 10 to 500 Å, and more preferably 100 to 300 Å. The thickness of the magnetic recording layer is about 50 Å to about 300 Å, more preferably 80 to 150 Å. The adhesion enhancement layer could be Ti, TiCr, Cr etc. with thickness of 10 to 50 Å. The overcoat cap layer could be hydrogenated, nitrogenated, hybrid or other forms of carbon with thickness of 10 to 80 Å, and more preferably 20 to 60 Å.

The magnetic recording medium has a remnant coercivity of about 2000 to about 10,000 Oersted, and an Mᵣt (product of remanence, Mr, and magnetic recording layer thickness, t) of about 0.2 to about 2.0 memu/cm². In a preferred embodiment, the coercivity is about 2500 to about 9000 Oersted, more preferably in the range of about 4000 to about 8000 Oersted, and most preferably in the range of about 4000 to about 7000 Oersted. In a preferred embodiment, the Mᵣt is about 0.25 to about 1 memu/cm², more preferably in the range of about 0.4 to about 0.9 memu/cm².

Almost all the manufacturing of a disk media takes place in clean rooms where the amount of dust in the atmosphere is kept very low, and is strictly controlled and monitored. After one or more cleaning processes on a non-magnetic substrate, the substrate has an ultra-clean surface and is ready for the deposition of layers of magnetic media on the substrate. The apparatus for depositing all the layers needed for such media could be a static sputter system or a pass-by system, where all the layers except the lubricant are deposited sequentially inside a suitable vacuum environment.

Each of the layers constituting magnetic recording media of the present invention, except for a carbon overcoat and a lubricant topcoat layer, may be deposited or otherwise formed by any suitable physical vapor deposition technique (PVD), e.g., sputtering, or by a combination of PVD techniques, i.e., sputtering, vacuum evaporation, etc., with sputtering being preferred. The carbon overcoat is typically deposited with sputtering or ion beam deposition. The lubricant layer is typically provided as a topcoat by dipping of the medium into a bath containing a solution of the lubricant compound, followed by removal of excess liquid, as by wiping, or by a vapor lube deposition method in a vacuum environment.

Sputtering is perhaps the most important step in the whole process of creating recording media. There are two types of sputtering: pass-by sputtering and static sputtering. In pass-by sputtering, disks are passed inside a vacuum chamber, where they are deposited with the magnetic and non-magnetic materials that are deposited as one or more layers on the substrate when the disks are moving. Static sputtering uses smaller machines, and each disk is picked up and deposited individually when the disks are not moving. The layers on the disk of the embodiment of this invention were deposited by static sputtering in a sputter machine.

The sputtered layers are deposited in what are called bombs, which are loaded onto the sputtering machine. The bombs are vacuum chambers with targets on either side. The substrate is lifted into the bomb and is deposited with the sputtered material.

A layer of lube is preferably applied to the carbon surface as one of the topcoat layers on the disk.

Sputtering leads to some particulates formation on the post sputter disks. These particulates need to be removed to ensure that they do not lead to the scratching between the head and substrate. Once a layer of lube is applied, the substrates move to the buffing stage, where the substrate is polished while it preferentially spins around a spindle. The disk is wiped and a clean lube is evenly applied on the surface.

Subsequently, in some cases, the disk is prepared and tested for quality thorough a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the disk.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

The implementations described above and other implementations are within the scope of the following claims.

What is claimed is:

1. A method of improving the corrosion performance of granular perpendicular recording media comprising depositing a top magnetic layer onto a granular layer using high sputter power and/or low sputter gas pressure.

2. The method of claim 1, wherein the sputter power is greater than about 0.8 kW.

3. The method of claim 1, wherein the sputter gas pressure is less than about 5 mTorr.

4. The method of claim 1, wherein the sputter power is greater than about 0.8 kW and the sputter gas pressure is less than about 5 mTorr.

5. The method of claim 1, wherein a thickness of the magnetic layer is from about 50 to about 80 Å.

6. The method of claim 5, wherein the thickness is about 65 Å.

7. A method of manufacturing a granular perpendicular magnetic recording medium comprising obtaining a substrate, depositing a granular layer, and depositing a top magnetic layer onto the granular layer, wherein the magnetic recording layer is deposited using high sputter power and/or low sputter gas pressure.

8. The method of claim 7, wherein the sputter power is greater than about 1.2 kW.

9. The method of claim 7, wherein the sputter gas pressure is less than about 60 mTorr.

10. The method of claim 7, wherein the sputter power is greater than about 1.2 kW and the sputter gas pressure is less than about 60 mTorr.

11. The method of claim 7, wherein a thickness of the magnetic layer is from about 90 to about 130 Å.

12. The method of claim 11, wherein the thickness is about 100 Å.
